(19) United States
(12) Patent Application Publication
(10) Pub. No.: US 2023/0115980 A1
(43) Pub. Date: Apr. 13, 2023

(54) MASKING LAYERS IN LED STRUCTURES

(71) Applicant: Applied Materials, Inc., Santa Clara, CA (US)

(72) Inventors: Michel Khoury, Mountain View, CA (US); Ria Someshwar, Mountain View, CA (US)

(73) Assignee: Applied Materials, Inc., Santa Clara, CA (US)

(21) Appl. No.: 17/498,373

(22) Filed: Oct. 11, 2021

(51) Int. Cl. H01L 33/00; H01L 33/32

(52) U.S. Cl. CPC H01L 33/0054; H01L 33/007; H01L 33/32

(57) ABSTRACT

Exemplary semiconductor processing methods may include providing a silicon-containing precursor to a processing region of a semiconductor processing chamber. A substrate may be disposed within the processing region of the semiconductor processing chamber. The substrate may include a nitrogen-containing nucleation layer deposited on the substrate. The methods may include forming a silicon-containing material on at least a first portion of the nitrogen-containing nucleation layer. The methods may include forming a second layer of material on at least a second portion of the nitrogen-containing nucleation layer. The methods may include forming a masking layer on a portion of the second layer of material. The masking layer may cover less than or about 90% of the second layer of material. The methods may include growing the second layer of material through the masking layer. The methods may include coalescing the second layer of material above the masking layer.

### TECHNICAL FIELD

The present technology relates to semiconductor processing and materials. More specifically, the present technology relates to formation processes and materials for light-emitting diode (“LED”) components.

### BACKGROUND

LED panels or devices may be formed with a number of light sources that operate as pixels on the device. The pixels may be formed with monochromatic light sources that are then delivered through a conversion layer to produce color, or the pixels may each have individual red, blue, and green light sources formed. In either scenario, any number up to millions of light sources may be formed and connected for operation. While there have been considerable developments to LEDs, LEDs may still encounter defects that lead to from reduced performance.

Thus, there is a need for improved systems and methods that can be used to produce high quality devices and structures. These and other needs are addressed by the present technology.

### SUMMARY

Exemplary semiconductor processing methods may include providing a silicon-containing precursor to a processing region of a semiconductor processing chamber. A substrate may be disposed within the processing region of the semiconductor processing chamber. The substrate may include a nitrogen-containing nucleation layer deposited on the substrate. The methods may include forming a silicon-containing material on at least a first portion of the nitrogen-containing nucleation layer. The first layer of material may be or include a dielectric material. The methods may include forming a second layer of material on at least a second portion of the nitrogen-containing nucleation layer. The second layer of material may include a gallium-containing material. The methods may include forming a masking layer on a portion of the second layer of material. The masking layer may cover less than or about 90% of the second layer of material. The methods may include growing the second layer of material through the masking layer. The methods may include coalescing the second layer of material above the masking layer.

In some embodiments, the gallium-containing material may be or include gallium nitride. The substrate may be or include silicon or sapphire. The nitrogen-containing nucleation layer may be or include gallium nitride (GaN), niobium nitride (NbN), hafnium nitride (HfN), or aluminum nitride (AlN). The methods may include, subsequent to forming the silicon-containing material, patterning the silicon containing material to expose one or more regions of the nitrogen-containing nucleation layer. The gallium containing material may be formed selectively on the one or more regions of the nitrogen-containing nucleation layer. The dielectric material may be or include silicon nitride. Coalescing the second layer of material may cause threading dislocations in the gallium-containing material to bend and extend laterally outward within the gallium-containing material. Growing the layer of material through the masking layer may include forming additional gallium-containing material through gaps in the masking layer. The masking layer of material may be characterized by a thickness of less than or about 5 nm. Coalescing the second layer of material above the masking layer may form an upper portion of the second layer of material characterized by a pyramid shape.

Some embodiments of the present technology may encompass semiconductor processing methods. The methods may include forming a first layer of material on at least a first portion of a nitrogen-containing nucleation layer. The first layer of material may be or include a silicon-containing material. The methods may include forming a first portion of a second layer of material on at least a second portion of the nitrogen-containing nucleation layer. The second layer of material may be or include a gallium-containing material. The methods may include forming a discontinuous masking layer across the second layer of material and forming a second portion of the second layer of material. The first portion and second portion of the second layer of material may be partially separated by the masking layer. The second portion may be characterized by a pyramid shape.

In some embodiments, the discontinuous masking layer may cover less than or about 80% of the first portion of the second layer of material. The nitrogen-containing nucleation layer may be or include gallium nitride (GaN), niobium nitride (NbN), hafnium nitride (HfN), or aluminum nitride (AlN). The silicon-containing material may be or include silicon nitride. The masking layer of material may be formed in-situ. The masking layer of material may be characterized by a thickness of less than or about 5 nm.

Some embodiments of the present technology may encompass semiconductor structures. The structures may include a substrate, a nitrogen-containing nucleation layer formed on the substrate, a first layer of material extending across the nitrogen-containing nucleation layer, a gallium-containing material, and a discontinuous masking layer. The first layer of material may define one or more windows exposing portions of the nitrogen-containing nucleation layer. The first layer of material comprises a dielectric material. The gallium-containing material may be disposed within the windows defined by the first layer of material. The gallium-containing material may form a quantum well characterized by a pyramidal shape. The discontinuous masking layer may be incorporated within the gallium-containing material. The masking layer may be characterized by a thickness of less than or about 5 nm.

In some embodiments, the substrate may be or include silicon or sapphire. The nitrogen-containing nucleation layer may be or include gallium nitride (GaN), niobium nitride (NbN), hafnium nitride (HfN), or aluminum nitride (AlN). The dielectric material may be or include silicon nitride. The masking layer may be or include silicon nitride and may be characterized by a thickness of less than or about 3 nm.

Such technology may provide numerous benefits over conventional systems and techniques. For example, the present technology may provide a method for forming a masking layer that effectively reduces threading dislocations. Additionally, the present technology may utilize growth and/or formation methods that reduce the amount of threading dislocations that propagate to the surface of crystals grown in quantum wells. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows selected operations in a method of forming a light-emitting diode structure according to some embodiments of the present technology.

FIGS. 3A-3F illustrate a schematic view of a device developed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

LEDs are semiconductor light sources that emit light when current flows through them. Electrons in the semiconductor recombine with electron holes, releasing energy in the form of photons. Many conventional LEDS are formed with a thick film, such as thicker than a micron, that defines the quantum wells. Threading dislocations may propagate through the material in the quantum well from the underlying substrate and may result in nonradiative recombination in the quantum well region, where the LED emits a phonon instead of a photon. Threading dislocations in conventional technologies may readily pass through to the surface of the quantum well, which may undesirably increase the nonradiative recombination. Such threading dislocations may exist due to imperfections during the growth and/or formation process. These dislocations may carry through the subsequent device layers formed, including the LED active region, which may further reduce the efficiency of the device.

The present technology may overcome issues associated with conventional technologies by depositing a masking layer over a portion of the quantum well. The masking layer may be a dielectric material, such as silicon nitride as one non-limiting example. The masking layer may reduce the amount of threading dislocations able to propagate through the quantum well. This may improve the quality of the subsequently formed LED structure, which may improve efficiency of the device. Although the remaining disclosure will routinely identify specific LED materials and processes utilizing the disclosed technology, it will be readily understood that the systems and methods are equally applicable to a variety of materials and processes as may occur for producing displays. Accordingly, the technology should not be considered to be so limited as for use with LED processes alone. After discussing an exemplary chamber system that may be used according to some embodiments of the present technology, methods for producing high-quality structures will be described.

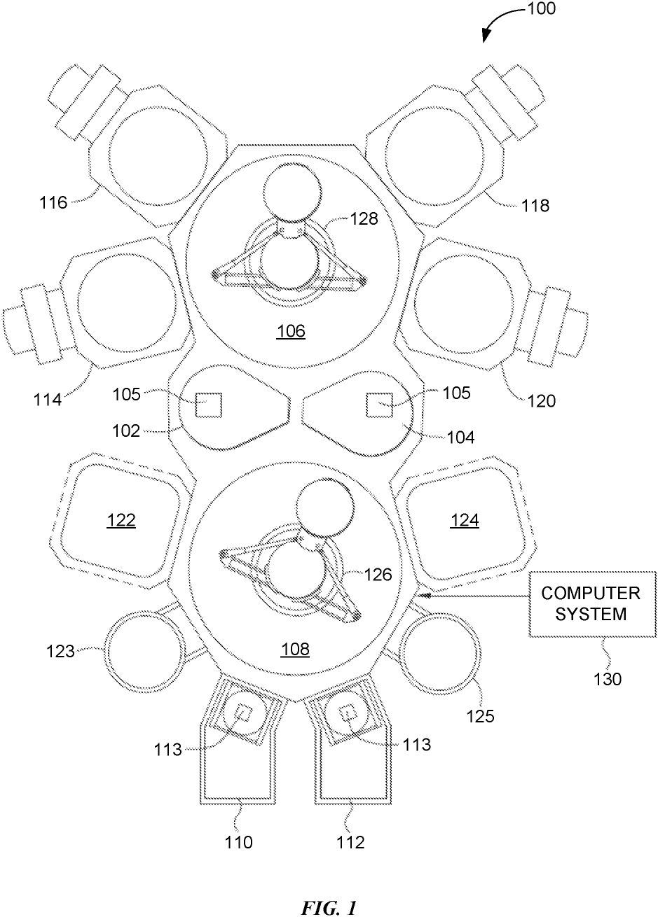

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

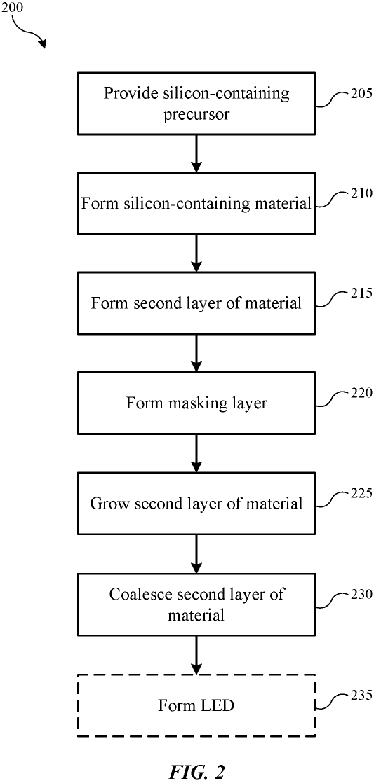

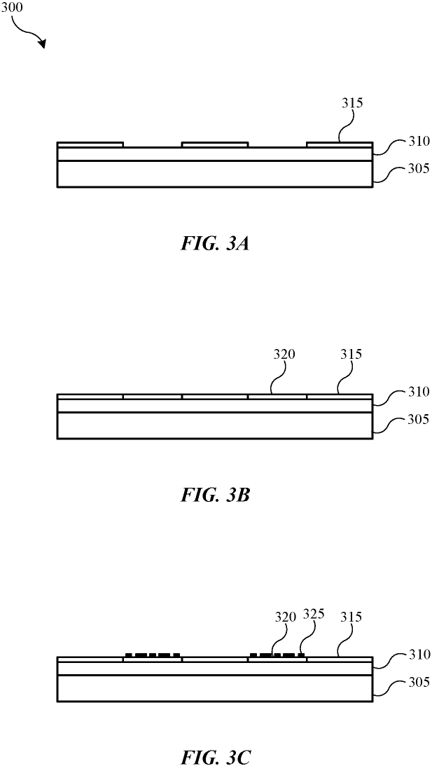

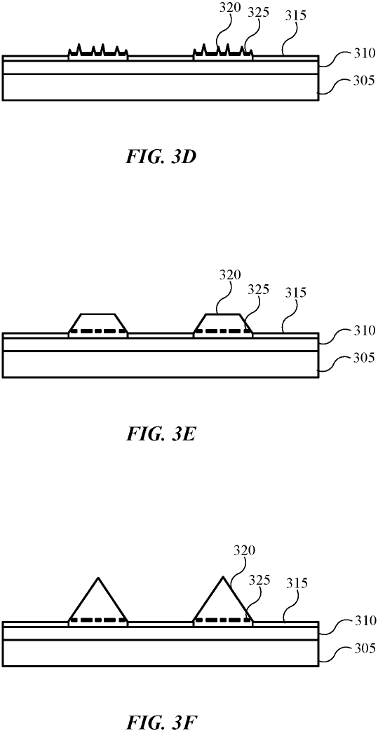

FIG. 2 illustrates selected operations of a semiconductor processing method 200. Method 200 may include one or more operations prior to the initiation of the method, including front end processing, deposition, etching, polishing, cleaning, or any other operations that may be performed prior to the described operations. For example, in some embodiments a degas operation may be performed on a substrate, such as silicon or sapphire substrate, to prepare the substrate for deposition. The method may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 200 describes operations shown schematically in FIGS. 3A-3F, the illustrations of which will be described in conjunction with the operations of method 200. It is to be understood that FIGS. 3A-3F illustrate only a partial schematic view, and a substrate may contain any number of sections having aspects as illustrated in the figure, as well as alternative structural aspects that may still benefit from aspects of the present technology.

Method 200 may involve optional operations to develop the structure to a particular fabrication operation. As illustrated in FIGS. 3A-3F, a substrate 305 may be used to facilitate a plurality of aspects being formed or grown overlying the substrate. Although only two aspects are illustrated, it is to be understood that a substrate may have hundreds, thousands, millions, or more aspects, and which may be any size. Substrate 305 may be any substrate on which structures may be formed, such as silicon-containing materials, aluminum materials, including sapphire, or any other materials as may be used in display or semiconductor fabrication. Substrate 305 may have a substantially planar surface or an uneven surface in embodiments. The substrate 305 may have various dimensions, such as 200 mm or 300 mm diameter wafers, as well as rectangular or square panels. The substrate 305 may be cleaned or processed in preparation for depositing one or more layers of material on the substrate for producing a structure, such as an LED, for example, although any number of other semiconductor structures may similarly benefit from aspects of the present technology.

A nitrogen-containing nucleation layer 310 may be formed overlying the substrate 305. The nitrogen-containing nucleation layer 310 may be or include, but is not limited to, gallium nitride (GaN), niobium nitride (NbN), hafnium nitride (HfN), or aluminum nitride (AlN). In embodiments, the nitrogen-containing nucleation layer may be, include, consist, or consist essentially of AlN. Further, in embodiments, the AlN nucleation layer may be deposited on a silicon substrate, and the AlN nucleation layer may be deposited on the silicon substrate through plasma vapor deposition. The nitrogen-containing nucleation layer 310 may allow for the subsequent formation of materials, such as gallium-containing material, as further discussed herein that may not be able to form directly on the substrate 305. That is, the nitrogen-containing nucleation layer 310 may serve as a seed layer for subsequent deposition operations in method 200.

Method 200 may include providing a silicon-containing precursor to a processing region of the semiconductor processing chamber at operation 205. Silicon-containing precursors that may be used in deposition may be or include any number of silicon-containing precursors. Accordingly, the silicon-containing precursor may be silane (SiH₄), disilane (Si₂H₆), trisilane (Si₃H₈), or other organosilanes including cyclohexasilanes, silicon tetrafluoride (SiF₄), silicon tetrachloride (SiCl₄), dichlorosilane (SiH₂Cl₂), or any other silicon-containing precursor used to form silicon-containing materials, including silicon nitride, for example. A nitrogen-containing precursor may also be provided to the region of the semiconductor processing chamber at operation 205. Nitrogen-containing precursors that may be used in deposition may be or include any number of nitrogen-containing precursors. Nitrogen-containing precursors used in any operation may include diatomic nitrogen (N₂), nitrous oxide (N₂O), nitrogen dioxide (NO₂), ammonia (NH₃), diazene (N₂H₂), as well as any other nitrogen-containing precursor that may be used in silicon nitride film formation. In some embodiments, ammonia may be provided at operation 205.

At operation 210, a first layer of material 315 may be formed over a first portion of the nitrogen-containing nucleation layer 310. As shown in FIG. 3A, the first layer of material 315 may be formed and patterned across the nitrogen-containing nucleation layer 310 such that gaps or windows are produced between the first layer of material 315, exposing portions of the underlying nitrogen-containing nucleation layer 310. These gaps or windows may be formed by patterning the first layer of material, also referred to as the silicon-containing material, to expose one or more regions of the nitrogen-containing nucleation layer. The first layer of material 315 may include a dielectric material. The first layer of material 315 may be a silicon-containing material, such as silicon nitride.

Referring to FIG. 3B, method 200 may include forming a second layer of material 320 on at least a second portion of the nitrogen-containing nucleation layer 310 at operation 215. The second layer of material 320 may be disposed within the gaps or windows defined by the first layer of material 315. The silicon-containing material on the first portion of the nitrogen-containing nucleation layer 310 and the second layer of material 320 on the second portion of the nitrogen-containing nucleation layer 310 may overlap slightly, but the two portions may also be distinct from one another. The second layer of material 320 may include a gallium-containing material, and in some embodiments may be gallium nitride. In embodiments where the two portions are distinct from one another, the gallium-containing material may be formed selectively on the one or more regions of the nitrogen-containing nucleation layer 310. The selective formation may be facilitated in gallium-containing materials forming over nucleation materials, but not the patterned dielectric material. For example, gallium nitride may be epitaxially grown extending from the exposed nucleation layer, which may allow selective formation in the open regions of the dielectric material 315, while limiting or preventing growth on the first layer of material 315.

As shown in FIG. 3C, at operation 220, a masking layer 325 may be formed on a portion of the second layer of material, or across the substrate. The masking layer 325 may cover less than all of the second layer of material 320. That is, the masking layer 325 may be discontinuous, such that a portion of the underlying second layer of material 320 remains uncovered and exposed. The masking layer 325 may be formed in-situ in the same chamber on which the layer of material 320 was formed, or any other chamber on the same or different processing tool. The masking layer 325 may include one or more monolayers of silicon nitride, as a non-limiting example, and may be formed to such a thickness that a complete layer may not be formed. Consequently, at least a portion of each second layer of material 320 may remain exposed through the masking layer 325. For example, by limiting timing of the deposition as explained below, the film may be formed to a thickness of less than or about 5 nm, and may be formed to a thickness of less than or about 4 nm, less than or about 3 nm, less than or about 2 nm, less than or about 1 nm, or less, which may ensure a complete layer is not produced, and islands of material may form across the substrate. This may maintain at least a certain open amount of exposed material 320. Similar to operation 205, a silicon-containing precursor and a nitrogen-containing precursor may also be provided to the region of the semiconductor processing chamber at operation 220 to form a masking layer 325 of silicon nitride.

It may be desirable to form the masking layer 325 at operation 220 in a relatively short time period. The shorter the period of time used to form the masking layer 325, the more discontinuous the masking layer 325 will be. Conversely, the longer the period of time used to form the masking layer 325, the more continuous the masking layer 325 will be. If the period of time for forming the masking layer 325 is too long of a time, the masking layer 325 may be continuous or substantially continuous, which may inhibit or reduce nucleation of the underlying second layer of material 320. Accordingly, the masking layer 325 may be formed in a period of time less than or about 10 minutes, such as less than or about 8 minutes, less than or about 6 minutes, less than or about 5 minutes, less than or about 4 minutes, less than or about 3 minutes, less than or about 2 minutes, less than or about 1 minute, less than or about 45 seconds, less than or about 30 seconds, or less. While dependent on the size of the gap or window in the first layer of material 315, a period of growth greater than 20 minutes may result in the masking layer 325 being continuous, which may prevent further growth of the second layer of material 320.

The specific timing used to deposit the masking layer 325 may result in the amount of discontinuity. In embodiments, the masking layer 325 may cover less than or about 90% of the second layer of material 320, such as less than or about 85%, less than or about 80%, less than or about 75%, less than or about 70%, less than or about 65%, less than or about 60%, less than or about 55%, less than or about 50%, less than or about 45%, less than or about 40%, less than or about 35%, less than or about 30%, less than or about 25%, or less. Similarly, to facilitate threading dislocation bending as explained further below, the masking layer 325 may cover greater than or about 10% of the second layer of material 320, such as greater than or about 15%, greater than or about 20%, greater than or about 25%, greater than or about 30%, or more. A greater amount of coverage of the second layer of material 320 means less openings in the masking layer 325 to the underlying second layer of material 320 and, therefore, the slower the subsequent growth of the second layer of material 320, as further described herein. Conversely, a lesser amount of coverage of the second layer of material 320 results in a faster subsequent growth of the second layer of material 320. This may also contribute to a greater amount of threading dislocation extension through the quantum well, which may further reduce device performance.

In conventional technologies, a thick planar film for the quantum well, such as greater than 1 micron, may be used without using a masking layer. As a result, threading dislocations may propagate through the thick planar film, which may have similar gaps or windows as the first layer of material 315 of the present disclosure. The present embodiments may reduce threading dislocations locally, and improve overall device efficiency, by using an additional masking layer 325 as previously described, which allows threading dislocation reduction at each aspect, such as at each LED pixel. A portion of threading dislocations propagating from the substrate 305 will be blocked by the masking layer 325. Further, a portion of threading dislocations passing the masking layer 325 may be caused to bend laterally through the quantum well region, and not pass out of the quantum well, due to the growth methods of the present embodiments.

Turning to FIG. 3D, the method 200 may include growing the second layer of material 320 through the masking layer 325 at operation 225. Growing the second layer of material 320 through the masking layer 325 may include forming additional gallium-containing material through gaps in the masking layer 325. The additional gallium-containing material may be a second portion of the second layer of material 320, which may also be referred to as an upper portion. The second portion of the second layer of material 320 may be partially separated from a first portion of the second layer of material 320 by the masking layer 325. As previously discussed, the rate of growth of the second layer of material 320 may depend on the coverage of the masking layer 325. A greater amount of coverage by the masking layer 325 may result in a slower rate of growth, whereas a lesser amount of coverage by the masking layer 325 may result in a faster rate of growth. This is because the masking layer 325 may reduce exposed portions of the second layer of material 320 during operation 225 where the second layer of material 320 may be further grown or formed. Further, a greater amount of coverage by the masking layer 325 may result in fewer threading dislocations propagating through the second layer of material 320, whereas a lesser amount of coverage by the masking layer 325 may result in more threading dislocations propagating through the second layer of material 320.

As the second portion of the second layer of material 320 grows above the masking layer 325, a plurality of protrusions of the second layer of material 320 may form above and through the masking layer 325. As previously discussed, a portion of threading dislocations propagating from the substrate 305 will be blocked by the masking layer 325. Another portion of threading dislocations propagating from the substrate 305 may bend and remain buried in the basal plane as they reach portions where the plurality of protrusions were formed prior to forming the final pyramid, as will be further described below. The formation of the plurality of protrusions in the second layer of material 320 may enable threading dislocation bending in the second layer of material 320. This may decrease the amount of threading dislocations reaching the final surface of the second layer of material 320. Reduced threading dislocations at the surface may result in less nonradiative recombination in the quantum well region.

At operation 230, the method 200 may include coalescing the second layer of material 320 above the masking layer 325. Coalescing the second layer of material 320 above the masking layer 325 may form an upper portion of the second layer of material 320, which may also be referred to as the second portion. The upper portion of the second layer of material 320 may be characterized by a pyramid shape, which may be formed progressively during the formation. That is, coalescing the second layer of material 320 may combine the plurality of protrusions extending above the masking layer 325 at operation 225 to form one pyramidal structure as shown in FIGS. 3E-3F. This coalescence of the second layer of material 320 may be referred to as local coalescence, or coalescence of the second layer of material 320 only above the gaps in the masking layer 325. Local coalescence is differentiated by a more global coalescence where the second layer of material 320 could coalesce into a flat film on the masking layer 325 instead of the pyramidal structures shown in FIGS. 3E-3F. Coalescing the second layer of material 320 may cause threading dislocations in the gallium-containing material to bend along certain facet intersections, and extend laterally outward within the gallium-containing material. The plurality of protrusions formed at operation 225 and shown in FIG. 3D may allow the threading dislocations propagating through the sidewalls of the pyramid, not the uppermost point, to bend at a 90° angle and extend laterally to the side of the final sidewall of the pyramid shown in FIG. 3F. This bending may reduce or eliminate nonradiative recombination in the quantum well region. By bending threading dislocations in the basal plane, the upper portion of the second layer of material, such as the upper portion of the pyramid, may have few threading dislocations and increase overall efficiency of the structure.

As previously discussed, the amount of coverage by the masking layer 325 may affect the rate of growth of the second layer of material 320 above the masking layer 325. Similarly, the amount of coverage by the masking layer 325 may affect the amount of the second layer of material 320 above the masking layer 325 necessary to form the pyramids. For example, with more coverage by the masking layer 325, a greater amount of material above the masking layer 325 may be needed to coalesce the material into a pyramid shape. In some embodiments with less masking, only a few hundred nm of growth above the masking layer 325 is necessary to form the pyramids, whereas with more masking, a few microns of growth above the masking layer 325 may be necessary to form the pyramids. Thus, by balancing the extent of coverage of the masking layer 325, a more controlled growth and timing may be produced to deposit enough material in the second layer of material 320 above the masking layer to form the pyramids.

After forming the structure 300, the method 200 may further include forming an LED structure at operation 235. Embodiments of forming an LED structure at operation 235 may include forming a p-doped layer on the second layer of material 320 above the masking layer 325 of structure 300. The p-doped layer may be made from one or more of gallium nitride (GaN), aluminum-indium-gallium-nitride (AlInGaN), indium-gallium-nitride (InGaN), and aluminum-gallium nitride (AlGaN). In further embodiments, the p-doped layer may include gallium-free, indium-and-nitride materials such as indium nitride (InN), and aluminum-indium-nitride (AlInN), among other gallium-free nitride materials. Forming an LED structure at operation 235 may additionally include forming contact pads on the layers of the structure 300. The contact pads may be made from one or more electrically conductive materials such as copper, aluminum, tungsten, chromium, nickel, silver, gold, platinum, palladium, titanium, tin, and/or indium, among other conductive materials. Any additional or alternative operations or processes for forming an LED structure may be included as one skilled in the art will appreciate.

Operation 235 may also include forming a light conversion region on the LED structure. The light conversion region may absorb the light emitted by the LED structure and emit light at a longer wavelength from an LED display. In embodiments, the light conversion region may be a quantum-dot layer. In additional embodiments, the quantum dot layer may be operable to convert a shorter wavelength of light from the LED structure into one of red, green, or blue light. Additional quantum-dot-layers may be formed on other LED structures to convert the shorter wavelength of light emitted by the LED structure into another of the red, green, and blue colored light. In further embodiments, combinations of three quantum-dot-layers on three LED structures may form a LED pixel that includes subpixels operable to emit red, green, and blue light. In more embodiments, sequential operations may form a red quantum dot layer in one of the subpixels of each LED pixel, then form a green quantum dot layer in another one of the subpixels, and then form a blue quantum dot layer in still another one of the subpixels. Following the formation of the blue quantum dot, each LED pixel in the array of LED pixels may include red, green, and blue subpixels.

Embodiments of the present disclosure, such as method 200 and the structure 300, include operations and structures that limit the amount of threading dislocations extending through the quantum well. As previously discussed, threading dislocations may decrease efficiency and performance of the resulting structure. By using an intermittent masking layer, such as the discontinuous masking layer 325 described herein, these threading dislocations can be reduced, which may also reduce the amount of nonradiative recombination and maintain operation of the structure, such as an LED, as intended. Thus, embodiments of the present technology provide fabrication methods for structures with reduced amounts of threading dislocation for the improved efficiency of light-emitting diodes.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either limit of the range, both limits of the range, or neither limit of the range are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such precursors, and reference to “the nitrogen-containing nucleation layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor to a processing region of a semiconductor processing chamber, wherein a substrate is disposed within the processing region of the semiconductor processing chamber, and wherein the substrate comprises a nitrogen-containing nucleation layer deposited on the substrate;
forming a silicon-containing material on at least a first portion of the nitrogen-containing nucleation layer, wherein the silicon-containing material comprises a dielectric material;
forming a second layer of material on at least a second portion of the nitrogen-containing nucleation layer, wherein the second layer of material comprises a gallium-containing material;
forming a masking layer on a portion of the second layer of material, wherein the masking layer covers less than or about 90% of the second layer of material;
growing the second layer of material through the masking layer; and
coalescing the second layer of material above the masking layer.

2. The semiconductor processing method of claim 1, wherein the gallium-containing material is gallium nitride.

3. The semiconductor processing method of claim 1, wherein the substrate comprises silicon or sapphire.

4. The semiconductor processing method of claim 1, wherein the nitrogen-containing nucleation layer comprises gallium nitride (GaN), niobium nitride (NbN), hafnium nitride (HfN), or aluminum nitride (A1N).

5. The semiconductor processing method of claim 1, further comprising:
subsequent to forming the silicon-containing material, patterning the silicon containing material to expose one or more regions of the nitrogen-containing nucleation layer, and wherein the gallium containing material is formed selectively on the one or more regions of the nitrogen-containing nucleation layer.

6. The semiconductor processing method of claim 1, wherein the dielectric material comprises silicon nitride.

7. The semiconductor processing method of claim 1, wherein the coalescing the second layer of material causes threading dislocations in the gallium-containing material to bend and extend laterally outward within the gallium-containing material.

8. The semiconductor processing method of claim 1, wherein growing the layer of material through the masking layer comprises forming additional gallium-containing material through gaps in the masking layer.

9. The semiconductor processing method of claim 1, wherein the masking layer of material is characterized by a thickness of less than or about 5 nm.

10. The semiconductor processing method of claim 1, wherein coalescing the second layer of material above the masking layer forms an upper portion of the second layer of material characterized by a pyramid shape.

11. A semiconductor processing method comprising:
forming a first layer of material on at least a first portion of a nitrogen-containing nucleation layer, wherein the first layer of material comprises a silicon-containing material;
forming a first portion of a second layer of material on at least a second portion of the nitrogen-containing nucleation layer, wherein the second layer of material comprises a gallium-containing material;
forming a discontinuous masking layer across the second layer of material;
forming a second portion of the second layer of material, wherein the first portion and second portion of the second layer of material are partially separated by the masking layer, and wherein the second portion is characterized by a pyramid shape.

12. The semiconductor processing method of claim 11, wherein the discontinuous masking layer covers less than or about 80% of the first portion of the second layer of material.

13. The semiconductor processing method of claim 11, wherein the nitrogen-containing nucleation layer comprises gallium nitride (GaN), niobium nitride (NbN), hafnium nitride (HfN), or aluminum nitride (A1N).

14. The semiconductor processing method of claim 11, wherein the silicon-containing material comprises silicon nitride.

15. The semiconductor processing method of claim 14, wherein the masking layer of material is formed in-situ, and wherein the masking layer of material is characterized by a thickness of less than or about 5 nm.

16. A semiconductor structure comprising:
a substrate;
a nitrogen-containing nucleation layer formed on the substrate;
a first layer of material extending across the nitrogen-containing nucleation layer, wherein the first layer of material defines one or more windows exposing portions of the nitrogen-containing nucleation layer, and wherein the first layer of material comprises a dielectric material;
a gallium-containing material disposed within the windows defined by the first layer of material, and forming a quantum well characterized by a pyramidal shape; and
a discontinuous masking layer incorporated within the gallium-containing material, wherein the masking layer is characterized by a thickness of less than or about 5 nm.

17. The semiconductor structure of claim 16, wherein the substrate comprises silicon or sapphire.

18. The semiconductor structure of claim 16, wherein the nitrogen-containing nucleation layer comprises gallium nitride (GaN), niobium nitride (NbN), hafnium nitride (HfN), or aluminum nitride (A1N).

19. The semiconductor structure of claim 16, wherein the dielectric material comprises silicon nitride.

20. The semiconductor structure of claim 16, wherein the masking layer is silicon nitride and is characterized by a thickness of less than or about 50 nm.
